(19) United States
(12) Patent Application Publication
(10) Pub. No.: US 2025/0161969 A1
(43) Pub. Date: May 22, 2025

(54) MASK SHEET, METHOD OF MANUFACTURING MASK ASSEMBLY, AND APPARATUS FOR MANUFACTURING DISPLAY DEVICE

(71) Applicant: Samsung Display Co., LTD., Yongin-si (KR)

(72) Inventor: Sangha PARK, Yongin-si (KR)

(21) Appl. No.: 18/751,202

(22) Filed: Jun. 22, 2024

(30) Foreign Application Priority Data
Nov. 20, 2023 (KR) 10-2023-0161030

(51) Int. Cl. B05B 12/28

(52) U.S. Cl. CPC B05B 12/28

(57) ABSTRACT

A mask sheet fixed to a mask frame includes a first zone in which a plurality of holes are arranged, a second zone outside the first zone and including an edge of the mask sheet, a third zone between the first zone and the second zone and fixed to the mask frame, and a plurality of grooves arranged in the second zone.

### CROSS-REFERENCE TO RELATED APPLICATION

This application claims priority to Korean Patent Application No. 10-2023-0161030, filed on Nov. 20, 2023, and all the benefits accruing therefrom under 35 U.S.C. § 119, the content of which in its entirety is herein incorporated by reference.

### BACKGROUND

### 1. Field

One or more embodiments relate to a deposition mask (hereinafter, a mask) which may be used to deposit a material with a certain pattern in association with manufacturing a display device, and more particularly, to a fine metal mask (FMM).

### 2. Description of the Related Art

Display devices may provide an image by emitting light through a plurality of pixels. The pixels of display devices may be implemented by forming various layers including an emission layer on a substrate. The various layers may be formed by depositing a deposition material on the substrate and may also be formed with a certain pattern. A mask may be used to deposit a deposition material with a certain pattern.

### SUMMARY

A mask or mask assembly may be manufactured by fixing (e.g., welding) a mask sheet on a mask frame. The mask sheet may include a plurality of fine openings to allow a deposition material to pass through in a certain pattern. To fix the mask sheet onto the mask frame in a flat state, the mask sheet may be fixed on the mask frame with tensile force applied to the mask sheet in a certain direction. In some aspects, due to the thinness of the mask sheet and the tensile force on the mask sheet, waves may appear on a surface of the mask sheet.

Additional aspects will be set forth in part in the description which follows and, in part, will be apparent from the description, or may be learned by practice of the presented embodiments of the disclosure.

According to one or more embodiments, a mask sheet fixed to a mask frame includes a first zone in which a plurality of holes are arranged, a second zone outside the first zone and including an edge of the mask sheet, a third zone between the first zone and the second zone and fixed to the mask frame, and a plurality of grooves arranged in the second zone.

According to one or more embodiments, in a plan view, the mask sheet may include a short side and a long side longer than the short side, wherein the plurality of grooves may extend in a direction in which the short side extends.

According to one or more embodiments, the first zone may include a first subzone overlapping the plurality of holes and a second subzone surrounding the first subzone, wherein a length of at least one of the plurality of grooves in the direction in which the short side extends may be greater than a length of the first subzone in the direction in which the short side extends.

According to one or more embodiments, the plurality of grooves may include a first groove arranged in a first surface of the mask sheet, and a second groove arranged in a second surface of the mask sheet opposite to the first surface.

According to one or more embodiments, at least one of a depth of the first groove and a depth of the second groove may be equal to or less than half a thickness of the mask sheet.

According to one or more embodiments, the first groove and the second groove may each be provided in plurality, wherein the plurality of first grooves may be alternately arranged with the plurality of second grooves.

According to one or more embodiments, the first groove may be provided in plurality, wherein a space between adjacent first grooves of the plurality of first grooves may be equal to a width of each of the first grooves.

According to one or more embodiments, the plurality of grooves may be arranged in a grid form.

According to one or more embodiments, a method of manufacturing a mask assembly includes preparing a mask frame including an opening in the center and preparing a mask sheet, wherein the mask sheet includes a first zone in which a plurality of holes are arranged, aligning the mask frame and the mask sheet with each other such that the opening included in the mask frame and the first zone included in the mask sheet overlap each other, tensioning the mask sheet in one direction by applying tensile force to the mask sheet, fixing the mask sheet to the mask frame, and removing a second zone of the mask sheet protruding beyond an edge of the mask frame, wherein the mask sheet includes a plurality of grooves arranged in the second zone.

According to one or more embodiments, in a plan view, the mask sheet may include a short side and a long side longer than the short side, wherein the plurality of grooves may extend in a direction in which the short side extends.

According to one or more embodiments, the first zone may include a first subzone overlapping the plurality of holes in the mask sheet and a second subzone surrounding the first subzone, wherein a length of at least one of the plurality of grooves in the direction in which the short side extends may be greater than a length of the first subzone in the direction in which the short side extends.

According to one or more embodiments, the plurality of grooves may include a first groove arranged in a first surface of the mask sheet, and a second groove arranged in a second surface of the mask sheet opposite to the first surface.

According to one or more embodiments, at least one of a depth of the first groove and a depth of the second groove may be equal to or less than half a thickness of the mask sheet.

According to one or more embodiments, the first groove and the second groove may each be provided in plurality, wherein the plurality of first grooves may be alternately arranged with the plurality of second grooves.

According to one or more embodiments, the first groove may be provided in plurality, wherein a space between adjacent first grooves of the plurality of first grooves may be equal to a width of each of the first grooves.

According to one or more embodiments, the plurality of grooves may be arranged in a grid form.

According to one or more embodiments, an apparatus for manufacturing a display device includes a mask assembly, and a deposition source facing the mask assembly and configured to spray a deposition material toward the mask assembly, wherein the mask assembly is manufactured by a method including preparing a mask frame including an opening in the center and preparing a mask sheet, wherein the mask sheet includes a first zone in which a plurality of holes are arranged, aligning the mask frame and the mask sheet with each other such that the opening included in the mask frame and the first zone included in the mask sheet overlap each other, tensioning the mask sheet in one direction by applying tensile force to the mask sheet, fixing the mask sheet to the mask frame, and removing a second zone of the mask sheet protruding beyond an edge of the mask frame, wherein the mask sheet includes a plurality of grooves arranged in the second zone.

According to one or more embodiments, in a plan view, the mask sheet may include a short side and a long side longer than the short side, wherein the plurality of grooves may extend in a direction in which the short side extends.

According to one or more embodiments, the plurality of grooves may include a first groove arranged in a first surface of the mask sheet, and a second groove arranged in a second surface of the mask sheet opposite to the first surface.

According to one or more embodiments, the plurality of grooves may be arranged in a grid form.

### BRIEF DESCRIPTION OF THE DRAWINGS

The above and other aspects, features, and advantages of certain embodiments of the disclosure will be more apparent from the following description taken in conjunction with the accompanying drawings, in which:

FIG. 1 is a cross-sectional view of an apparatus for manufacturing a display device, according to an embodiment;

FIG. 2 is an exploded perspective view of a mask assembly according to an embodiment;

FIG. 3A is a perspective view of an operation in a process of a method of manufacturing a mask assembly, according to an embodiment;

FIG. 3B is a perspective view of an operation in a process of a method of manufacturing a mask assembly, according to an embodiment;

FIG. 3C is a perspective view of an operation in a process of a method of manufacturing a mask assembly, according to an embodiment;

FIG. 3D is a perspective view of an operation in a process of a method of manufacturing a mask assembly, according to an embodiment;

FIG. 3E is a perspective view of an operation in a process of a method of manufacturing a mask assembly, according to an embodiment;

FIG. 4 is a plan view of a mask sheet according to an embodiment;

FIG. 5 is a plan view of a mask sheet according to another embodiment;

FIG. 6 is a plan view of a mask sheet according to another embodiment;

FIG. 7 is a cross-sectional view of a mask sheet according to an embodiment;

FIG. 8 is a cross-sectional view of a mask sheet according to another embodiment;

FIG. 9 is a cross-sectional view of a mask sheet according to another embodiment;

FIG. 10 is a cross-sectional view of a mask sheet according to another embodiment;

FIG. 11 is a cross-sectional view of a mask sheet according to another embodiment;

FIG. 12 is a plan view of a display device manufactured using an apparatus for manufacturing a display device, according to an embodiment; and

FIG. 13 is a cross-sectional view of the display device of FIG. 12, taken along a line XIII-XIII′ of FIG. 12.

### DETAILED DESCRIPTION

Reference will now be made in detail to embodiments, examples of which are illustrated in the accompanying drawings, wherein like reference numerals refer to like elements throughout. In some aspects, the present embodiments may have different forms and should not be construed as being limited to the descriptions set forth herein. Accordingly, the embodiments are merely described herein, by referring to the figures, to explain aspects of the present description. As used herein, the term “and/or” includes any and all combinations of one or more of the associated listed items. Throughout the disclosure, the expression “at least one of a, b or c” indicates only a, only b, only c, both a and b, both a and c, both b and c, all of a, b, and c, or variations thereof.

As the present description allows for various changes and numerous embodiments, certain embodiments will be illustrated in the drawings and described in the written description. Effects and features of one or more embodiments and methods of accomplishing the same will become apparent from the following detailed description of the one or more embodiments, taken in conjunction with the accompanying drawings. However, the present embodiments may have different forms and should not be construed as being limited to the descriptions set forth herein.

One or more embodiments will be described herein in more detail with reference to the accompanying drawings. Those elements that are the same or are in correspondence with each other are rendered the same reference numeral regardless of the figure number, and redundant descriptions thereof are omitted.

While such terms as “first” and “second” may be used to describe various elements, such elements must not be limited to the above terms. The above terms are used to distinguish one element from another.

The singular forms “a,” “an,” and “the” as used herein are intended to include the plural forms as well unless the context clearly indicates otherwise.

It will be understood that the terms “include,” “comprise,” and “have” as used herein specify the presence of stated features or elements but do not preclude the addition of one or more other features or elements.

It will be further understood that, when a layer, region, or element is referred to as being on another layer, region, or element, the layer, region, or element may be directly or indirectly on the other layer, region, or element. That is, for example, intervening layers, regions, or elements may be present.

Sizes of elements in the drawings may be exaggerated or reduced for convenience of explanation. For example, since sizes and thicknesses of elements in the drawings are arbitrarily illustrated for convenience of explanation, the following embodiments are not limited thereto.

A first direction DR1, a second direction DR2, and a third direction DR3 are not limited to three directions of the rectangular coordinate system and may be interpreted in a broader sense. For example, the first direction DR1, the second direction DR2, and the third direction DR3 may be perpendicular to one another or may represent different directions that are not perpendicular to one another.

When an embodiment may be implemented differently, a certain process order may be performed differently from the described order. For example, two consecutively described processes may be performed substantially at the same time or performed in an order opposite to the described order. The term “substantially,” as used herein, means approximately or actually.

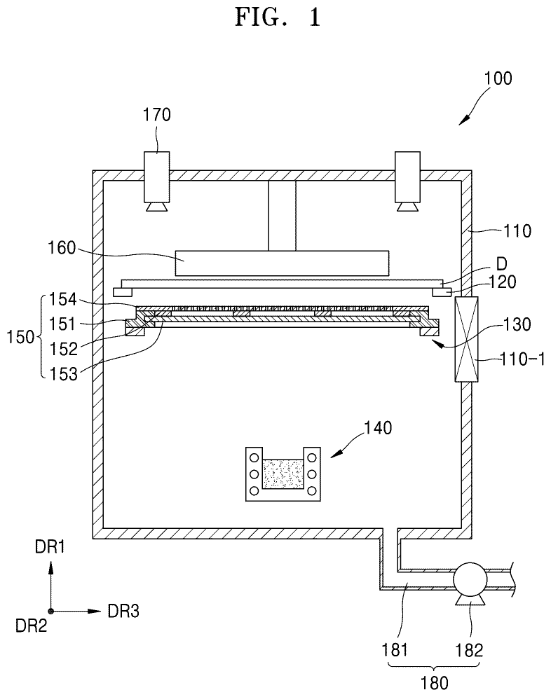

FIG. 1 is a cross-sectional view of an apparatus 100 for manufacturing a display device, according to an embodiment.

Referring to FIG. 1, the apparatus 100 may include a chamber 110, a first support 120, a second support 130, a deposition source 140, a mask assembly 150, a magnetic force portion 160, a vision portion 170, and a pressure controller 180.

The chamber 110 may include a space therein, and a portion of the chamber 110 may be open. In some aspects, a gate valve 110-1 may be installed in the open portion of the chamber 110. In this example case, the open portion of the chamber 110 may be opened or closed according to an operation of the gate valve 110-1.

The first support 120 may support a display substrate D. For example, the display substrate D may be seated on the first support 120. In an embodiment, the first support 120 may be in the form of a plate fixed inside the chamber 110. In another embodiment, the first support 120 may be in the form of a shuttle linearly moveable in the chamber 110, and the display substrate D may be seated on the first support 120. In another embodiment, the first support 120 may include an electrostatic chuck or adhesive chuck arranged in the chamber 110, and the electrostatic chuck or adhesive chuck may be fixed to the chamber 110 or be capable of being raised or lowered in the chamber 110. Hereinafter, an example case where the first support 120 is in the form of a plate fixed inside the chamber 110 will be mainly described for convenience.

The mask assembly 150 may be seated on the second support 130. In some aspects, the second support 130 may be arranged inside the chamber 110. The second support 130 may support fine-adjustments to a position of the mask assembly 150. In an embodiment, the second support 130 may include a separate driver or alignment unit for moving the mask assembly 150 in different directions. In another embodiment, the second support 130 may be in the form of a shuttle movable in one or more of the different directions. In this example case, the mask assembly 150 may be seated on the second support 130, and the second support 130 may transport the mask assembly 150. For example, the second support 130 may move out of the chamber 110, the mask assembly 150 may be seated on the second support 130, and the second support 130 may then enter the chamber 110 from outside the chamber 110.

The first support 120 and the second support 130 may be integrally formed with each other. In this example case, the first support 120 and the second support 130 may include a movable shuttle. In some aspects, the first support 120 and the second support 130 may include a structure of fixing the mask assembly 150 and the display substrate D such that the display substrate D is seated on the mask assembly 150, and the first support 120 and the second support 130 may linearly move the display substrate D and the mask assembly 150 simultaneously.

Hereinafter, a form in which the first support 120 and the second support 130 are distinct from each other and arranged at different positions and a form in which the first support 120 and the second support 130 are arranged inside the chamber 110 will be mainly described for convenience.

The deposition source 140 may face the mask assembly 150. In some aspects, a deposition material may be accommodated in the deposition source 140, and the deposition material may be evaporated or sublimated by heating the deposition material. The deposition source 140 may be fixed inside the chamber 110 or may be arranged inside the chamber 110 to be linearly moveable in one direction. Hereinafter, an example case where the deposition source 140 is fixed inside the chamber 110 will be mainly described for convenience.

The mask assembly 150 may include a mask frame 151, first support sticks 152, second support sticks 153, and a tensile sheet 154. The first support sticks 152 and second support sticks 153 may also be referred to as support members.

The magnetic force portion 160 may be arranged inside the chamber 110 to face the display substrate D. In some aspects, the magnetic force portion 160 may apply magnetic force to the tensile sheet 154, thereby pressing the mask assembly 150 toward the display substrate D. In particular, the magnetic force portion 160 may prevent the tensile sheet 154 from sagging downward and may also bring the tensile sheet 154 into close contact with the display substrate D. In some aspects, the apparatus 100 may maintain the magnetic force portion 160 according to a uniform distance between the tensile sheet 154 and the display substrate D with respect to a length direction of the tensile sheet 154.

The vision portion 170 may be installed at the chamber 110 and may capture positions of the display substrate D and the mask assembly 150. In some aspects, the vision portion 170 may include a camera for capturing images of the display substrate D and the mask assembly 150. Positions of the display substrate D and the mask assembly 150 may be identified based on the images captured by the vision portion 170, and based on the images, the first support 120 may fine-adjust the position of the display substrate D or the second support 130 may fine-adjust the position of the mask assembly 150. Hereinafter, an example case where the second support 130 fine-adjusts a position of the mask assembly 150 to align positions of the display substrate D and the mask assembly 150 with each other will be mainly described. The term “fine-adjust” may refer to adjustments based on a predetermined increment amount.

The pressure controller 180 may be connected to the chamber 110 and may be configured to control the internal pressure of the chamber 110. For example, the pressure controller 180 may adjust the internal pressure of the chamber 110 to a level that is equal to or similar to (e.g., within a threshold amount) the pressure level of atmospheric pressure. In some aspects, the pressure controller 180 may adjust the internal pressure of the chamber 110 to a level that is equal to or similar to (e.g., within a threshold amount) the pressure level of a vacuum state.

The pressure controller 180 may include a connection pipe 181 connected to the chamber 110 and a pump 182 installed at the connection pipe 181. In some aspects, based on an operation of the pump 182, external air may flow in through the connection pipe 181 or gas inside the chamber 110 may be guided to the outside through the connection pipe 181.

The above apparatus 100 may be used to manufacture a display device described herein. First, in an example in which the pressure controller 180 adjusts the internal pressure of the chamber 110 to a level that is equal to or similar to (e.g., within a threshold amount) the pressure level of atmospheric pressure, the gate valve 110-1 may operate to open the open portion of the chamber 110.

After the open the open portion of the chamber 110 is opened, the display substrate D may be inserted into the chamber 110 from outside the chamber 110. In some aspects, the display substrate D may be inserted into the chamber 110 in various ways. For example, the display substrate D may be inserted into the chamber 110 from outside the chamber 110 through a robot arm or other robotic equipment arranged outside the chamber 110. In another embodiment, in an example in which the first support 120 is in the form of a shuttle, the first support 120 may be carried out of the chamber 110 from inside the chamber 110, and then, the display substrate D may be seated on the first support 120 through a separate robot arm or robotic equipment arranged outside the chamber 110, and the first support 120 may be inserted into the chamber 110 from outside the chamber 110. Hereinafter, an example case where the display substrate D is inserted into the chamber 110 from outside the chamber 110 through a robot arm arranged outside the chamber 110 will be mainly described for convenience.

As described herein, the mask assembly 150 may be arranged inside the chamber 110. In another embodiment, in the same or similar manner as the display substrate D, the mask assembly 150 may be inserted into the chamber 110 from outside the chamber 110. Hereinafter, an example case where only the display substrate D is inserted into the chamber 110 from outside the chamber 110 with the mask assembly 150 arranged inside the chamber 110 will be mainly described for convenience.

In another embodiment, the first support 120 and the second support 130 may be in the form of a shuttle, and the display substrate D and the mask assembly 150 may be fixed thereon and then may be inserted into the chamber 110 from outside the chamber 110.

When the display substrate D is inserted into the chamber 110, the display substrate D may be seated on the first support 120. In some aspects, the vision portion 170 may capture positions of the display substrate D and the mask assembly 150. In particular, the vision portion 170 may capture images of a first alignment mark of the display substrate D and a second alignment mark of the mask assembly 150.

Based on the captured images of the first alignment mark and the second alignment mark, positions of the display substrate D and the mask assembly 150 may be identified. In some aspects, the apparatus 100 may include a separate controller configured to identify positions of the display substrate D and the mask assembly 150.

Once positions of the display substrate D and the mask assembly 150 are identified, the second support 130 may fine-adjust the position of the mask assembly 150.

After the fine-adjustment of the position of the mask assembly 150, the deposition source 140 may operate to spray a deposition material toward the mask assembly 150 (e.g., in the first direction DR1), and the deposition material having passed through a plurality of openings in the tensile sheet 154 may be deposited on the display substrate D. In some aspects, the pump 182 may suction in gas from inside the chamber 110 and discharge the gas to the outside, thereby maintaining the internal pressure of the chamber 110 at a level that is equal to or similar to (e.g., within a threshold amount) the pressure level of a vacuum state.

The apparatus 100 may deposit the deposition material onto the display substrate D by passing the deposition material through an opening arranged in a deposition area (not illustrated). In some aspects, the mask assembly 150 may provide a deposition area that is equal to or similar to (e.g., within a threshold amount) a designed deposition area.

The above operations may be repeatedly performed on a plurality of display substrates D. In some aspects, when the quantity of depositions on the plurality of display substrates D becomes equal to a preset quantity of depositions, the apparatus 100 may stop operating, and the mask assembly 150 may be drawn out of the chamber 110.

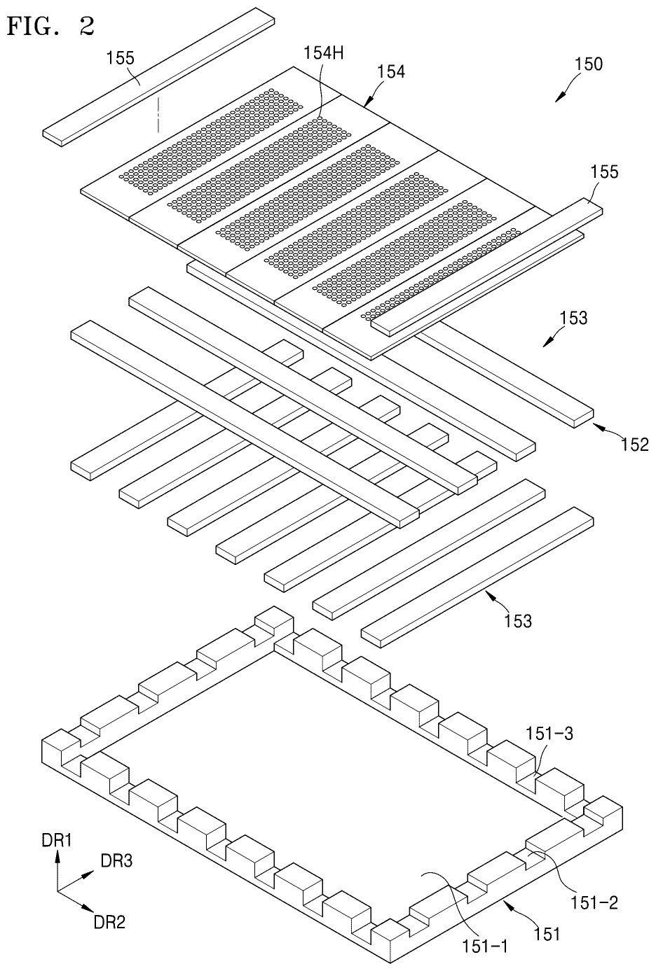

FIG. 2 is an exploded perspective view of the mask assembly 150 according to an embodiment.

Referring to FIG. 2, the mask assembly 150 may include the mask frame 151, the first support sticks 152, the second support sticks 153, and the tensile sheet 154.

The mask frame 151 may have a plurality of frames connected to one another and forming an interior space of the mask frame 151. In an embodiment, the mask frame 151 may be in the form of a frame with one opening 151-1 in the center. In another embodiment, the mask frame 151 may be in a grid form such as, for example, a window frame including a plurality of openings. Hereinafter, an example case where the mask frame 151 includes one opening 151-1 in the center will be mainly described for convenience. In some aspects, a length of one side (or a long side) of the mask frame 151 may be greater than a length of another side (or a short side) the mask frame 151. In an embodiment, one side of the mask frame 151 extending in the second direction DR2 may be defined as a long side of the mask frame 151, and one side of the mask frame 151 extending in the third direction DR3 may be defined as a short side of the mask frame 151. A length of the long side of the mask frame 151 may be greater than a length of the short side of the mask frame 151.

The mask frame 151 may include a first groove 151-2 and a second groove 151-3 in a surface of the mask frame 151 (e.g., a surface facing the first direction DR1). In an example, the first groove 151-2 and the second groove 151-3 do not penetrate the mask frame 151 in the first direction DR1 and may be arranged at regular intervals. For example, the first groove 151-2 may include a plurality of first grooves 151-2, may be spatially connected to the opening 151-1 of the mask frame 151, and may be arranged in the third direction DR3. Similarly, the second groove 151-3 may include a plurality of second grooves 151-3, may be spatially connected to the opening 151-1 of the mask frame 151, and may be arranged in the second direction DR2. The first grooves 151-2 and the second grooves 151-3 may provide spaces into which both ends of each of the first support sticks 152 and the second support sticks 153 may be inserted to the mask frame 151 such that the first support sticks 152 and the second support sticks 153 are fixed to the mask frame 151. The first groove 151-2 may penetrate the mask frame 151 in the second direction DR2. The second groove 151-3 may penetrate the mask frame 151 in the third direction DR3.

The first support sticks 152 and the second support sticks 153 may be disposed on the mask frame 151. In some aspects, each of the first support sticks 152 and the second support sticks 153 may be provided in plurality and may be disposed on the mask frame 151 to be apart from another. For example, the plurality of first support sticks 152 may be spaced apart parallel to one side of the tensile sheet 154, and the plurality of second support sticks 153 may be spaced apart parallel to another side of the tensile sheet 154. In an embodiment, the first support stick 152 may extend in the second direction DR2 and may be arranged in the third direction DR3. The first support stick 152 may be parallel to the long side of the mask frame 151.

The second support stick 153 may extend in the third direction DR3 and may be arranged in the second direction DR2. The second support stick 153 may be parallel to the short side of the mask frame 151. In another embodiment, the first support stick 152 may be omitted, and the second support stick 153 (or multiple the second support sticks 153) may be disposed on the mask frame 151. In another embodiment, the second support stick 153 may be omitted, and the first support stick 152 (or multiple first support sticks 152) may be disposed on the mask frame 151.

In an embodiment, both ends of the first support stick 152 may be inserted in the first groove 151-2 and thus may be fixed to the mask frame 151, and both ends of the second support stick 153 may be inserted in the second groove 151-3 and thus may be fixed to the mask frame 151. In some aspects, both side surfaces of the first support stick 152 may be coplanar with both side surfaces of the mask frame 151. For example, a side surface of the first support stick 152 facing the second direction DR2 may be coplanar with a side surface of the mask frame 151 facing the second direction DR2. Similarly, both side surfaces of the second support stick 153 may be coplanar with both side surfaces of the mask frame 151. For example, a side surface of the second support stick 153 facing the third direction DR3 may be coplanar with a side surface of the mask frame 151 facing the third direction DR3. In another embodiment, the first grooves 151-2 and the second grooves 151-3 may be omitted, and the first support stick 152 and/or the second support stick 153 may be directly disposed (e.g., welded) on an upper surface of the mask frame 151 facing the first direction DR1. Although FIG. 2 illustrates four first support sticks 152 and seven second support sticks 153, one or more embodiments are not necessarily limited to the quantities of first support sticks 152 and second support sticks 153.

The tensile sheet 154 may include at least one tensile sheet 154. In an example in which the tensile sheet 154 includes at least two tensile sheets 154, the at least two tensile sheets 154 may extend in one direction (e.g., the third direction DR3) and may be arranged in another direction (e.g., the second direction DR2). In this example case, one side of the tensile sheet 154 extending in the third direction DR3 may be understood as a long side of the tensile sheet 154, and one side of the tensile sheet 154 extending in the second direction DR2 may be understood as a short side of the tensile sheet 154. In an embodiment, the first support stick 152 extending in the second direction DR2 may cross a plurality of tensile sheets 154, and the second support stick 153 extending in the third direction DR3 may simultaneously overlap two tensile sheets 154 adjacent to each other.

The tensile sheet 154 may include at least one hole 154H. For example, a plurality of holes 154H may be formed in the tensile sheet 154 in a length direction (e.g., the third direction DR3) of the tensile sheet 154. In some aspects, the plurality of holes 154H may be apart from each other by a certain distance in one direction (e.g., the second direction DR2) and may penetrate the tensile sheet 154. In an embodiment, some of the holes 154H in the tensile sheet 154 may overlap the first support stick 152.

The tensile sheet 154 may be coupled onto the mask frame 151. For example, the tensile sheet 154 may be welded on an upper surface (or a surface facing the first direction DR1) of the mask frame 151. Each tensile sheet 154 may be in direct contact with other tensile sheets 154 (e.g., adjacent tensile sheets 154) or spaced apart from other tensile sheets 154. In an example in which each tensile sheet 154 is spaced apart from other tensile sheets 154, a portion of the second support stick 153 may be exposed in the separated area.

One edge of the tensile sheets 154 and one edge of the mask frame 151 may be in contact with each other. In an embodiment, an edge of the tensile sheet 154 extending in the second direction DR2 (e.g., a short side of the tensile sheet 154) and an edge of the mask frame 151 extending in the second direction DR2 (e.g., a long side of the mask frame 151) may be in contact with each other and may be coplanar with each other.

An alignment stick 155 may be arranged on one side of an outermost tensile sheet 154 included among the tensile sheets 154. In an embodiment, one alignment stick 155 extending in the third direction DR3 may be arranged on a side in the second direction DR2 of an outermost tensile sheet 154 in the second direction DR2 among a plurality of tensile sheets 154. In some aspects, one alignment stick 155 extending in the third direction DR3 may be arranged on a side in a direction opposite to the second direction DR2 of an outermost tensile sheet 154 in the direction opposite to the second direction DR2 among the plurality of tensile sheets 154. The alignment stick 155 may be in direct contact with or apart from the tensile sheet 154. The alignment stick 155 may serve as the second alignment mark of the mask assembly 150 described herein with reference to FIG. 1.

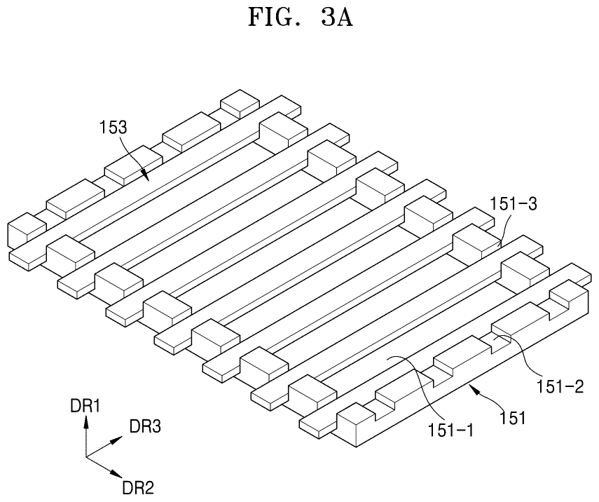

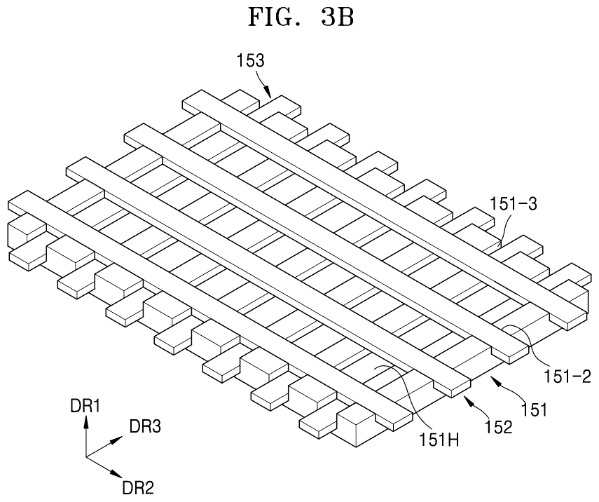

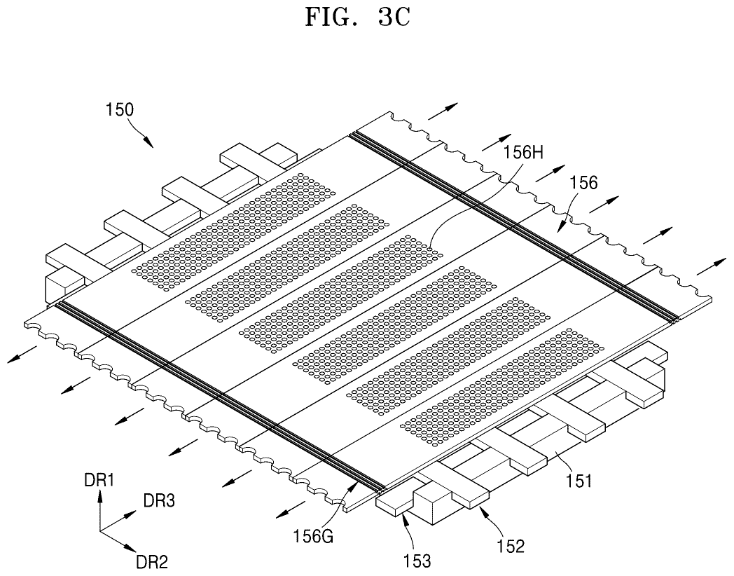

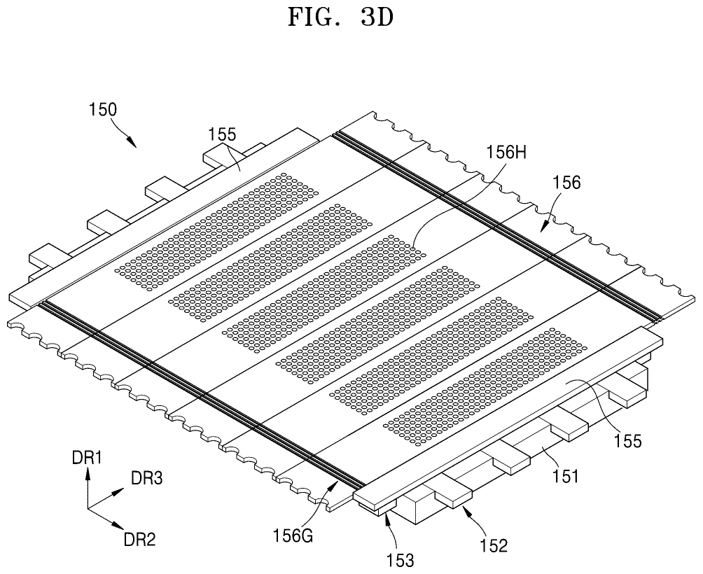

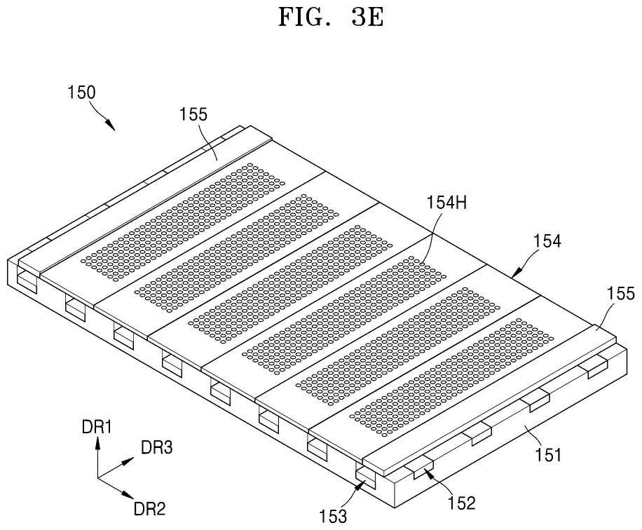

FIG. 3A is a perspective view of an operation in a process of a method of manufacturing a mask assembly, according to an embodiment.

Referring to FIG. 3A, the method may include coupling second support sticks 153 to the mask frame 151. The second support stick 153 may include a plurality of second support sticks 153, and each of the second support sticks 153 may be arranged parallel to a short side (or a side extending in the third direction DR3) of the mask frame 151. After arranging each of the second support sticks 153, the method may include overlapping each of the second support sticks 153 with corresponding second grooves 151-3 of the mask frame 151, and then, pushing the second support sticks 153 into the corresponding second grooves 151-3 in a direction opposite to the first direction DR1. In an embodiment, the second groove 151-3 may be shaped such that a width of the second groove 151-3 (e.g., a length of the second groove 151-3 in the second direction DR2) is equal to a width of the second support stick 153. In the current operation of the process, the second support sticks 153 may protrude out of the mask frame 151. In an embodiment, the method may include welding the second support stick 153 the second groove 151-3. In another embodiment, unlike that illustrated in FIG. 3A, the second groove 151-3 may be omitted, and the method may include welding the second support stick 153 onto an upper surface of the mask frame 151 facing the first direction DR1.

FIG. 3B is a perspective view of an operation in a process of a method of manufacturing a mask assembly, according to an embodiment.

Referring to FIG. 3B, the method may include disposing first support sticks 152 on the embodiment illustrated in FIG. 3A. The first support sticks 152 may be coupled to the mask frame 151. The first support stick 152 may include a plurality of first support sticks 152, and the method may include arranging each of the first support sticks 152 parallel to a long side (or a side extending in the second direction DR2) of the mask frame 151. After arranging each of the first support sticks 152, the method may include overlapping each of the first support sticks 152 with corresponding first grooves 151-2 of the mask frame 151, and then, pushing the first support sticks 152 into the corresponding first grooves 151-2 in the direction opposite to the first direction DR1. In an embodiment, the first groove 151-2 may be shaped such that a width of the first groove 151-2 (e.g., a length of the first groove 151-2 in the third direction DR3) is equal to a width of the first support stick 152. A depth (or a length in the first direction DR1) of the first groove 151-2 may be less than a depth (or a length in the first direction DR1) of the second groove 151-3.

Accordingly, the first support stick 152 may be positioned in the first direction DR1 with respect to the second support stick 153. The first support stick 152 may cross the second support stick 153, and a portion of the first support stick 152 may overlap a portion of the second support stick 153. The first support sticks 152 and the second support sticks 153 may cross each other and define a plurality of holes 151H. In the current operation of the process, each of the first support sticks 152 and the second support sticks 153 may protrude out of the mask frame 151. In an embodiment, the first support stick 152 may additionally be welded to the first groove 151-2. In another embodiment, unlike that illustrated in FIG. 3B, the first groove 151-2 may be omitted, and the first support stick 152 may be welded on an upper surface of the mask frame 151 facing the first direction DR1.

FIG. 3C is a perspective view of an operation in a process of a method of manufacturing a mask assembly, according to an embodiment.

Referring to FIG. 3C, the method may include disposing a mask sheet 156 onto the embodiment illustrated in FIG. 3B. The method may include disposing the mask sheet 156 onto the mask frame 151 while tensioning the mask sheet 156, for example, by applying a certain force in one direction (e.g., the third direction DR3 and the opposite direction) to maintain flatness. The mask sheet 156 may include a plurality of holes 156H apart from each other. The mask sheet 156 may be aligned with the mask frame 151 such that the holes 156H in the mask sheet 156 and the holes 151H (refer to FIG. 3B) defined by the first support sticks 152 and the second support sticks 153 overlap each other, and the method may include welding the mask sheet 156 to the mask frame 151. For example, in an area where the mask frame 151 and the mask sheet 156 overlap each other, the mask sheet 156 may be welded to the mask frame 151.

Because the mask sheet 156 may be welded and fixed to the mask frame 151 while being tensioned, the mask frame 151 may be bent or deformed by receiving force from the mask sheet 156. In some aspects, the first support sticks 152 and the second support sticks 153 (refer to FIG. 3B) may support the mask frame 151, which may prevent deformation of the mask frame 151. The mask sheet 156 may include a plurality of mask sheets 156, and the method may include arranging the plurality of mask sheets 156 in one direction (e.g., the second direction DR2) and welding and fixing the plurality of mask sheets 156 to the mask frame 151.

A portion of the mask sheet 156 may protrude out of an area welded to the mask frame 151, for example, out of the mask frame 151. For example, a portion of the mask sheet 156 may protrude beyond an edge in the third direction DR3 of the mask frame 151 extending in the second direction DR2. Alternatively, a portion of the mask sheet 156 may protrude beyond an edge in a direction opposite to the third direction DR3, of the mask frame 151 extending in the second direction DR2.

Grooves 156G of the mask sheet 156 may be arranged in a portion of the mask sheet 156 that protrudes as described herein. In other words, the mask sheet 156 may be welded and fixed to the mask frame 151 and may include the grooves 156G arranged in an outer region of the mask frame 151.

The method may include tensioning the mask sheet 156 in a certain direction (e.g., the third direction DR3 and a direction opposite to the third direction DR3) and welding the mask sheet 156 to the mask frame 151. Accordingly, waves extending in the direction of tensioning (e.g., the third direction DR3) may appear on the mask sheet 156. Due to the waves, in an example in which the mask sheet 156 is fixed to the mask frame 151, the mask sheet 156 may have a curved shape in a direction (e.g., the first direction DR1) perpendicular to the direction of tensioning. The curved shape described herein may cause deformation in the holes 156H of the mask sheet 156, and as a result, may deteriorate deposition quality. The grooves 156G in the mask sheet 156 may reduce waves caused by preventing or mitigating a tensile force from forming in an area where the holes 156H of the mask sheet 156 are arranged.

FIG. 3D is a perspective view of an operation in a process of a method of manufacturing a mask assembly, according to an embodiment.

Referring to FIG. 3D, the method may include disposing the alignment stick 155 on the embodiment illustrated in FIG. 3C. The alignment stick 155 may extend in one direction (e.g., the third direction DR3) and may be arranged on both sides of the plurality of mask sheets 156. For example, the method may include arranging the alignment stick 155 in the second direction DR2 and a direction opposite to the second direction DR2 with respect to the plurality of mask sheets 156. In an embodiment, in the current operation of the process, a portion of the alignment stick 155 may protrude out of the mask frame 151. For example, a portion of the alignment stick 155 may extend beyond an edge of the mask frame 151 facing the third direction DR3 and/or the opposite direction. The method may include welding the alignment stick 155 and fixing the alignment stick 155 onto the mask frame 151.

FIG. 3E is a perspective view of an operation in a process of a method of manufacturing a mask assembly, according to an embodiment.

Referring to FIGS. 3D and 3E together, the method may include cutting off or removing a portion of the mask sheet 156. For example, the method may include cutting the mask sheets 156 along the long side of the mask frame 151 or in the second direction DR2. Accordingly, portions of the mask sheet 156 where the grooves 156G are formed may be removed and do not constitute part of the mask assembly 150. It may be understood that the tensile sheet 154 is obtained by removing the portions where the grooves 156G are formed from the mask sheet 156. It may be understood that the holes 156H in the mask sheet 156 and the holes 154H in the tensile sheet 154 refer to the same holes. After the cutting, an edge of a short side of the tensile sheet 154 may coincide with an edge of the long side of the mask frame 151.

The method may include cutting off (removing) respective portions of each of the first support stick 152, the second support stick 153, and the alignment stick 155 which protrude out of the mask frame. For example, a portion of the first support stick 152 protruding toward the second direction DR2 of the mask frame 151 or the opposite direction may be cut off and removed. A portion of the second support stick 153 protruding toward the third direction DR3 of the mask frame 151 or the opposite direction may be cut off and removed. Similarly, a portion of the alignment stick 155 protruding toward the third direction DR3 of the mask frame 151 or the opposite direction may be cut off and removed.

Accordingly, one surface (e.g., a surface facing the third direction DR3) of the second support stick 153, the tensile sheet 154, and the alignment stick 155 may be coplanar with one surface (e.g., a surface facing the third direction DR3) of the mask frame 151. One surface (e.g., a surface facing the second direction DR2) of the first support stick 152 may be coplanar with one surface (e.g., a surface facing the second direction DR2) of the mask frame 151.

In an embodiment, the method may include cutting the second support stick 153, the alignment stick 155, and the mask sheet 156 simultaneously. In an embodiment, the method may include cutting the first support stick 152, the second support stick 153, the alignment stick 155, and the mask sheet 156 simultaneously.

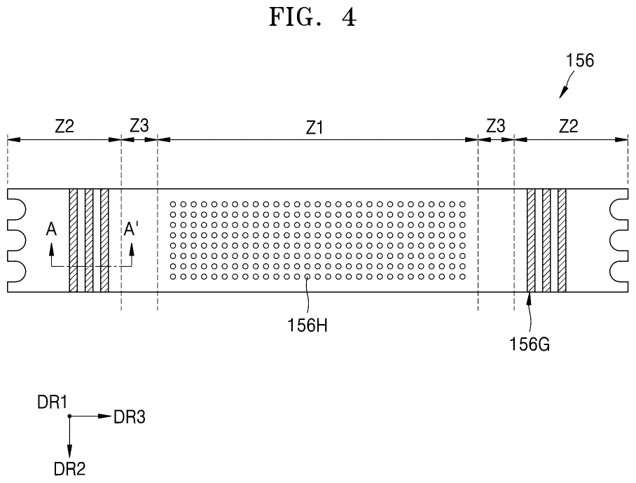

FIG. 4 is a plan view of the mask sheet 156 according to an embodiment.

Referring to FIG. 4, the mask sheet 156 may include a first zone Z1, a second zone Z2, and a third zone Z3 between the first zone Z1 and the second zone Z2. The first zone Z1 may be in the center of the mask sheet 156 and may be a zone where the holes 156H of the mask sheet 156 are arranged.

The second zone Z2 may include an edge of the mask sheet 156 and may be arranged outside the first zone Z1. In an embodiment, the second zone Z2 may include a plurality of second zones Z2, for example, two second zones Z2. The two second zones Z2 may respectively be on a side of the first zone Z1 in the third direction DR3 and on a side of the first zone Z1 in a direction opposite to the third direction DR3. An edge of the mask sheet 156 in the third direction DR3 or the opposite direction may be in the second zone Z2. In an example in which the mask sheet 156 is welded to a mask frame, a clamping point for tensioning the mask sheet 156 may be in the second zone Z2. The second zone Z2 may be a portion which is cut off and removed after the mask sheet 156 is welded to the mask frame. Accordingly, the second zone Z2 may be present in the mask sheet 156, but may not be present in the tensile sheet 154 (refer to FIG. 2), which results from welding and fixing the mask sheet 156 to the mask frame 151 (refer to FIG. 2).

The third zone Z3 may be between the first zone Z1 and the second zone Z2. In other words, the first zone Z1 and the second zone Z2 may be apart from each other due to the third zone Z3. The third zone Z3 may be a zone which overlaps a mask frame and is welded to the mask frame when the mask sheet 156 is fixed to the mask frame.

The mask sheet 156 may include a plurality of grooves 156G arranged in the second zone Z2. The grooves 156G may be arranged in each of the second zones Z2 on both sides of the first zone Z1. The grooves 156G may be apart from each other. A degree to which each groove 156G is apart from another, that is, a distance between the grooves 156G, may be constant. A width of each groove 156G may be constant. In an embodiment, the grooves 156G may have a stripe shape in which a length in the second direction DR2 is greater than a length in the third direction DR3.

The mask sheet 156 may include a long side extending in the third direction DR3 and a short side extending in the second direction DR2. The grooves 156G may extend in a short side direction of the mask sheet 156, for example, the second direction DR2. At least one of the grooves 156G may cross the mask sheet 156 in the second direction DR2. For example, a length of one of the grooves 156G in the second direction DR2 may be equal to a length of the mask sheet 156 in the second direction DR2.

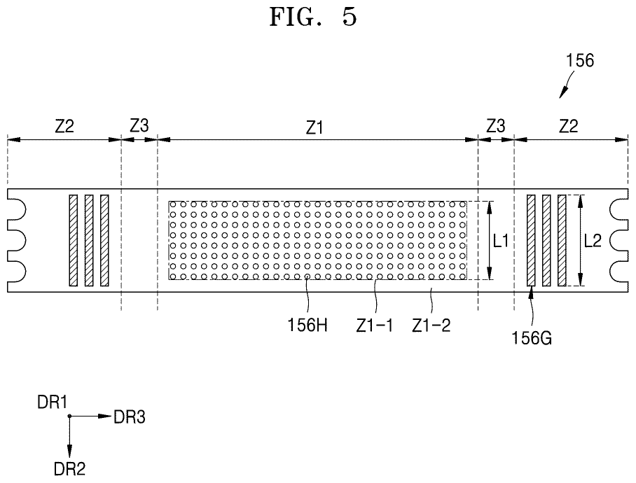

FIG. 5 is a plan view of the mask sheet 156 according to another embodiment.

Referring to FIG. 5, the groove 156G may not cross the mask sheet 156 in the second direction DR2. Expressed another way, in some embodiments, ends of the grooves 156G may be spaced apart from boundaries of the mask sheet 156.

The first zone Z1 may include a 1st-1 zone Z1-1 overlapping the holes 156H of the mask sheet 156 and a 1st-2 zone Z1-2 surrounding the 1st-1 zone Z1-1. In an embodiment, the 1st-2 zone Z1-2 may adjoin the third zone Z3, and the 1st-1 zone Z1-1 may be apart from the third zone Z3 due to the 1st-2 zone Z1-2. In some cases, the terms 1st-1 zone Z1-1 and 1st-2 zone Z1-2 may be referred to as subzones of the first zone Z1.

A length of the 1st-1 zone Z1-1 in the second direction DR2 may be defined as a first length L1. A length of the groove 156G in the second direction DR2 may be defined as a second length L2. The second length L2 may be equal to or greater than the first length L1.

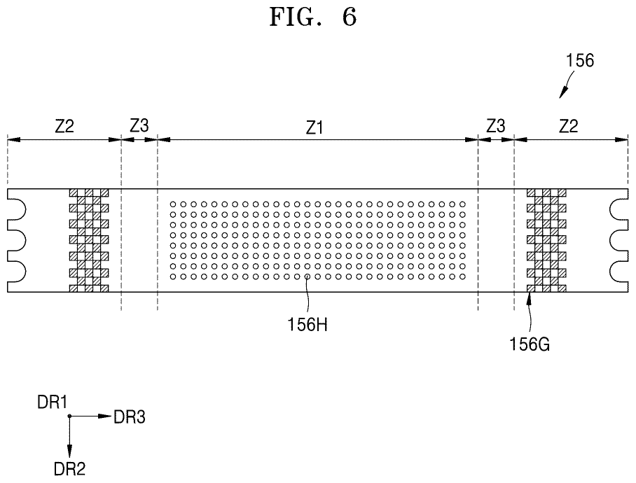

FIG. 6 is a plan view of the mask sheet 156 according to another embodiment.

Referring to FIG. 6, the grooves 156G in the mask sheet 156 may have a grid form. Expressed another way, the grooves 156G in the mask sheet 156 may be arranged in a grid form.

In an embodiment, a size of each grid may be the same. In an embodiment, each grid may have a square shape in which a length in the second direction DR2 is equal to a length in the third direction DR3. In another embodiment, unlike the square shape illustrated in FIG. 6, a shape of each grid may be a circle or an oval.

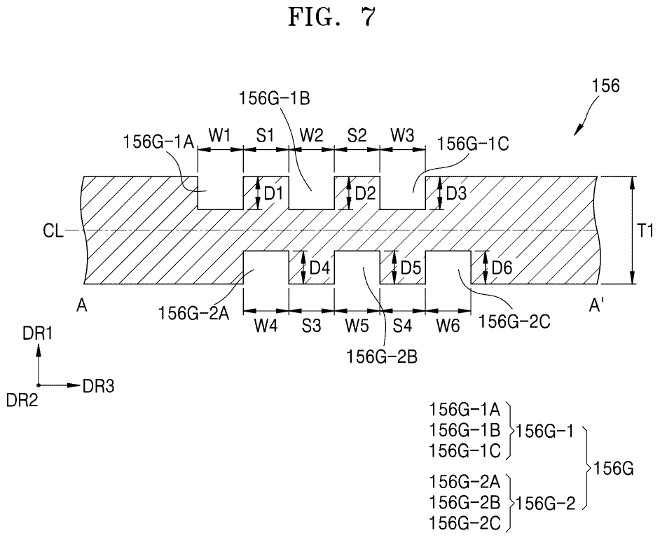

FIG. 7 is a cross-sectional view of the mask sheet 156 according to an embodiment.

FIG. 7 may be a cross-sectional view of an embodiment, taken along a line A-A′ of FIG. 4.

Referring to FIG. 7, a plurality of grooves 156G in the mask sheet 156 may include first grooves 156G-1 and second grooves 156G-2. The first grooves 156G-1 may be arranged in a first surface, for example, an upper surface or a surface facing the first direction DR1, of the mask sheet 156. The second grooves 156G-2 may be arranged in a second surface, for example, a lower surface or a surface facing a direction opposite to the first direction DR1, of the mask sheet 156.

In an embodiment, the first grooves 156G-1 may include 1st-1 to 1st-3 grooves 156G-1A, 156G-1B, and 156G-1C. In an embodiment, the second grooves 156G-2 may include 2nd-1 to 2nd-3 grooves 156G-2A, 156G-2B, and 156G-2C. Although FIG. 7 illustrates three first grooves 156G-1 and three second grooves 156G-2, this is an example, and one or more embodiments are not limited to such quantities.

In an embodiment, the first grooves 156G-1 may be alternately arranged with the second grooves 156G-2. In an embodiment, the 2nd-1 groove 156G-2A may be arranged between the 1st-1 groove 156G-1A and the 1st-2 groove 156G-1B. In an embodiment, the 2nd-2 groove 156G-2B may be arranged between the 1st-2 groove 156G-1B and the 1st-3 groove 156G-1C. In an embodiment, the 1st-2 groove 156G-1B may be arranged between the 2nd-1 groove 156G-2A and the 2nd-2 groove 156G-2B. In an embodiment, the 1st-3 groove 156G-1C may be arranged between the 2nd-2 groove 156G-2B and the 2nd-3 groove 156G-2C.

A depth of the 1st-1 groove 156G-1A may be defined as a first depth D1. A depth of the 1st-2 groove 156G-1B may be defined as a second depth D2. A depth of the 1st-3 groove 156G-1C may be defined as a third depth D3. A depth of the 2nd-1 groove 156G-2A may be defined as a fourth depth D4. A depth of the 2nd-2 groove 156G-2B may be defined as a fifth depth D5. A depth of the 2nd-3 groove 156G-2C may be defined as a sixth depth D6.

In an embodiment, a depth of each groove 156G may be the same. For example, the first to sixth depths D1, D2, D3, D4, D5, and D6 may be the equal to one another. Each groove 156G may have the same depth, and thus, tensile force applied in the third direction DR3 may be evenly distributed between the grooves 156G. In another embodiment, the first to third depths D1, D2, and D3 may be equal to one another and the fourth to sixth depths D4, D5, and D6 may be equal to one another, but the first depth D1 and the fourth depth D4 may be different from each other. In an example, the first to third depths D1, D2, and D3 may be different from the fourth to sixth depths D4, D5, and D6.

In an embodiment, each of the first to sixth depths D1, D2, D3, D4, D5, and D6 may be equal to or less than half a thickness T1 of the mask sheet 156. In other words, the first grooves 156G-1 and the second grooves 156G-2 may each be apart from a center line CL of the mask sheet 156. Each of the first to sixth depths D1, D2, D3, D4, D5, and D6 may be equal to or less than half the thickness T1 of the mask sheet 156, and thus, durability of the mask sheet 156 may be obtained.

A width (or a length in the third direction DR3) of the 1st-1 groove 156G-1A may be defined as a first width W1. A width (or a length in the third direction DR3) of the 1st-2 groove 156G-1B may be defined as a second width W2. A width (or a length in the third direction DR3) of the 1st-3 groove 156G-1C may be defined as a third width W3. A width (or a length in the third direction DR3) of the 2nd-1 groove 156G-2A may be defined as a fourth width W4. A width (or a length in the third direction DR3) of the 2nd-2 groove 156G-2B may be defined as a fifth width W5. A width (or a length in the third direction DR3) of the 2nd-3 groove 156G-2C may be defined as a sixth width W6.

In an embodiment, a width of each groove 156G may be the same. For example, the first to sixth widths W1, W2, W3, W4, W5, and W6 may be equal to one another. Each groove 156G may have the same width, and thus, tensile force applied in the third direction DR3 may be evenly distributed between the grooves 156G. In another embodiment, the first to third widths W1, W2, and W3 may be equal to one another and the fourth to sixth widths W4, W5, and W6 may be equal to one another, but the first width W1 and the fourth width W4 may be different from each other. In an example, the first to third widths W1, W2, and W3 may be different from the fourth to sixth widths W4, W5, and W6.

A space between the 1st-1 groove 156G-1A and the 1st-2 groove 156G-1B may be defined as a first space S1. A space between the 1st-2 groove 156G-1B and the 1st-3 groove 156G-1C may be defined as a second space S2. A space between the 2nd-1 groove 156G-2A and the 2nd-2 groove 156G-2B may be defined as a third space S3. A space between the 2nd-2 groove 156G-2B and the 2nd-3 groove 156G-2C may be defined as a fourth space S4.

In an embodiment, the first to fourth spaces S1, S2, S3, and S4 may be equal to one another. In an embodiment, the first to sixth widths W1, W2, W3, W4, W5, and W6 and the first to fourth spaces S1, S2, S3, and S4 may each be the same.

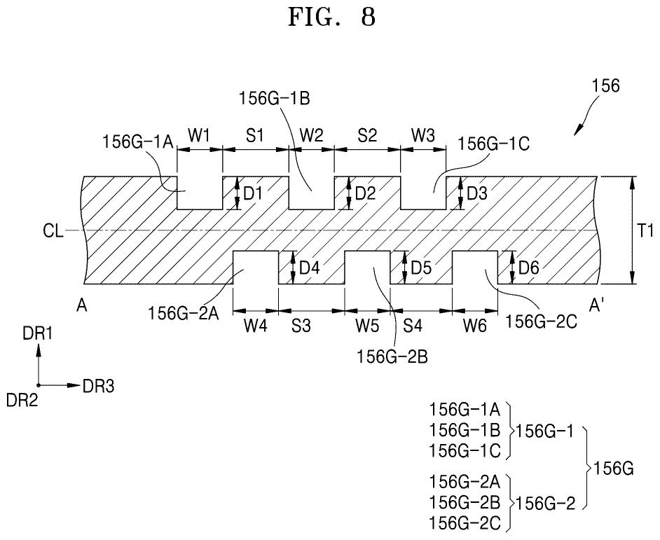

FIG. 8 is a cross-sectional view of the mask sheet 156 according to another embodiment.

FIG. 8 may be a cross-sectional view of another embodiment, taken along the line A-A′ of FIG. 4.

Referring to FIG. 8, the first to sixth widths W1, W2, W3, W4, W5, and W6 may be different from the first to fourth spaces S1, S2, S3, and S4. In an embodiment, each of the first to sixth widths W1, W2, W3, W4, W5, and W6 may be less than each of the first to fourth spaces S1, S2, S3, and S4. For example, the first to third widths W1, W2, and W3 of the first grooves 156G-1 may be less than the first and second spaces S1 and S2, which are spaces between the first grooves 156G-1. The fourth to sixth widths W4, W5, and W6 of the second grooves 156G-2 may be less than the third and fourth spaces S3 and S4, which are spaces between the second grooves 156G-2.

The fourth width W4 may overlap the first space S1 and may be less than the first space S1. The fifth width W5 may overlap the second space S2 and may be less than the second space S2. The second width W2 may overlap the third space S3 and may be less than the third space S3. The third width W3 may overlap the fourth space S4 and may be less than the fourth space S4.

Accordingly, the first grooves 156G-1 and the second grooves 156G-2 may be apart from each other in the third direction DR3. In an example in which a width of each groove 156G is less than a space between the grooves 156G, durability of the mask sheet 156 may be further obtained.

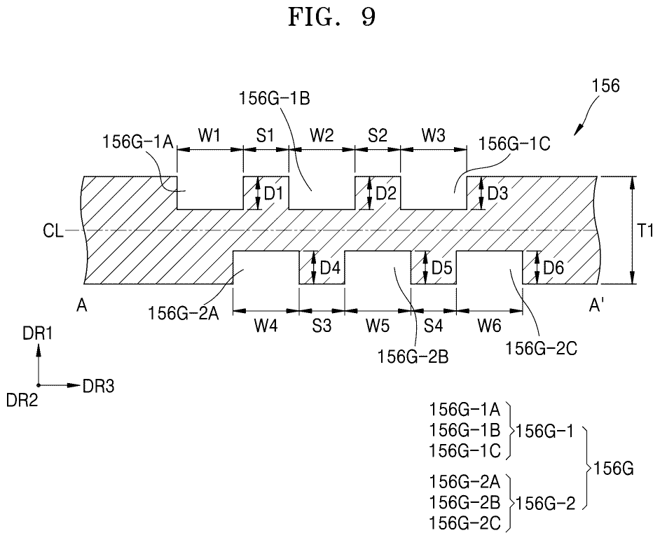

FIG. 9 is a cross-sectional view of the mask sheet 156 according to another embodiment.

FIG. 9 may be a cross-sectional view of another embodiment, taken along the line A-A′ of FIG. 4.

Referring to FIG. 9, the first to sixth widths W1, W2, W3, W4, W5, and W6 may be different from the first to fourth spaces S1, S2, S3, and S4. In an embodiment, each of the first to sixth widths W1, W2, W3, W4, W5, and W6 may be greater than each of the first to fourth spaces S1, S2, S3, and S4. For example, the first to third widths W1, W2, and W3 of the first grooves 156G-1 may be greater than the first and second spaces S1 and S2, which are spaces between the first grooves 156G-1. The fourth to sixth widths W4, W5, and W6 of the second grooves 156G-2 may be greater than the third and fourth spaces S3 and S4, which are spaces between the second grooves 156G-2.

The fourth width W4 may overlap the first space S1 and may be greater than the first space S1. The fifth width W5 may overlap the second space S2 and may be greater than the second space S2. The second width W2 may overlap the third space S3 and may be greater than the third space S3. The third width W3 may overlap the fourth space S4 and may be greater than the fourth space S4.

Accordingly, the first grooves 156G-1 and the second grooves 156G-2 may overlap each other in the first direction DR1. For example, the 1st-1 groove 156G-1A may overlap the 2nd-1 groove 156G-2A. The 1st-2 groove 156G-1B may overlap the 2nd-1 groove 156G-2A and the 2nd-2 groove 156G-2B. The 1st-3 groove 156G-1C may overlap the 2nd-2 groove 156G-2B and the 2nd-3 groove 156G-2C. The 2nd-1 groove 156G-2A may overlap the 1st-1 groove 156G-1A and the 1st-2 groove 156G-1B. The 2nd-2 groove 156G-2B may overlap the 1st-2 groove 156G-1B and the 1st-3 groove 156G-1C. The 2nd-3 groove 156G-2C may overlap the 1st-3 groove 156G-1C. In an example in which a width of each groove 156G is greater than a space between the grooves 156G, ability of the mask sheet 156 to distribute tensile force on the mask sheet 156 may be further improved.

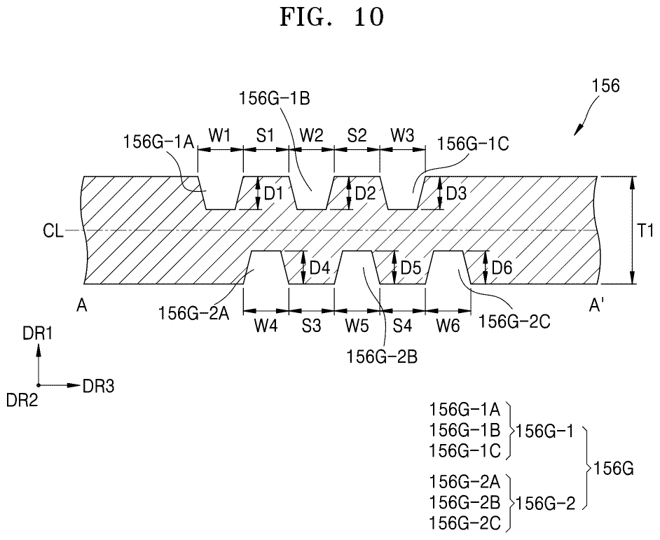

FIG. 10 is a cross-sectional view of the mask sheet 156 according to another embodiment.

FIG. 10 may be a cross-sectional view of another embodiment, taken along the line A-A′ of FIG. 4.

Referring to FIG. 10, the grooves 156G in the mask sheet 156 may have a tapered shape.

Hereinafter, an ‘upper side’ of the groove 156G may refer to a side adjacent to a surface of the mask sheet 156. A ‘lower side’ of the groove 156G may refer to a side opposite to the ‘upper side’ and adjacent to the center line CL of the mask sheet 156. For example, an upper side of the first grooves 156G-1 may refer to a side adjacent to an upper surface of the mask sheet 156 facing the first direction DR1, and a lower side of the first grooves 156G-1 may refer to a side adjacent to the center line CL of the mask sheet 156. An upper side of the second grooves 156G-2 may refer to a side adjacent to a lower surface of the mask sheet 156 facing a direction opposite to the first direction DR1, and a lower side of the second grooves 156G-2 may refer to a side adjacent to the center line CL of the mask sheet 156. Accordingly, the upper side of the first grooves 156G-1 and the upper side of the second grooves 156G-2 may be apart from each other by the thickness T1 of the mask sheet 156.

In an embodiment, a width of the upper side of the first grooves 156G-1, for example, the first to third widths W1, W2, and W3, may be greater than a width of the corresponding lower side of the first grooves 156G-1. In an embodiment, a width of the upper side of the second grooves 156G-2, for example, the fourth to sixth widths W4, W5, and W6, may be greater than a width of the corresponding lower side of the second grooves 156G-2.

In another embodiment, a width of the upper side of the first grooves 156G-1, for example, the first to third widths W1, W2, and W3, may be less than a width of the corresponding lower side of the first grooves 156G-1. In another embodiment, a width of the upper side of the second grooves 156G-2, for example, the fourth to sixth widths W4, W5, and W6, may be less than a width of the corresponding lower side of the second grooves 156G-2.

In an embodiment, each of the first to sixth widths W1, W2, W3, W4, W5, and W6 may be equal to the first to fourth spaces S1, S2, S3, and S4. Accordingly, a width of the lower side of each of the first grooves 156G-1 and a width of the lower side of each of the second grooves 156G-2 may be less than the first to fourth spaces S1, S2, S3, and S4.

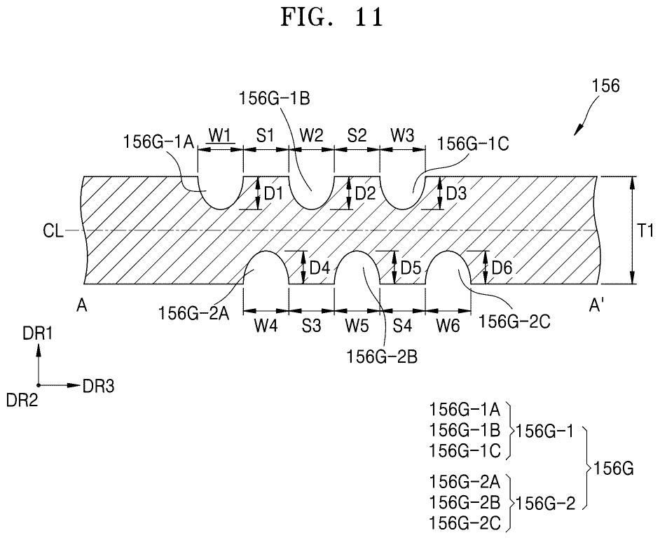

FIG. 11 is a cross-sectional view of the mask sheet 156 according to another embodiment.

FIG. 11 may be a cross-sectional view of another embodiment, taken along the line A-A′ of FIG. 4.

Referring to FIG. 11, the grooves 156G in the mask sheet 156 may have a substantially semicircular shape. In some aspects, a diameter of each semicircle may be the same as the first to sixth widths W1, W2, W3, W4, W5, and W6.

In another embodiment, a cross-sectional shape of the grooves 156G may be variously modified into, for example, a semi-oval, a triangle, an N-gon (where N is a natural number of 5 or greater), or an hourglass shape.

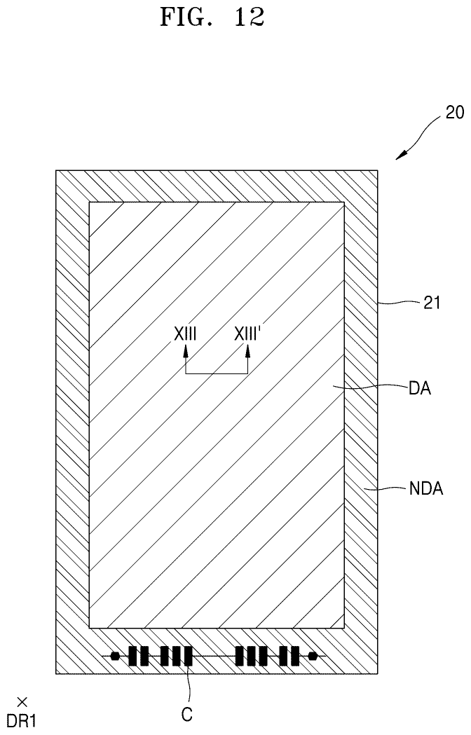

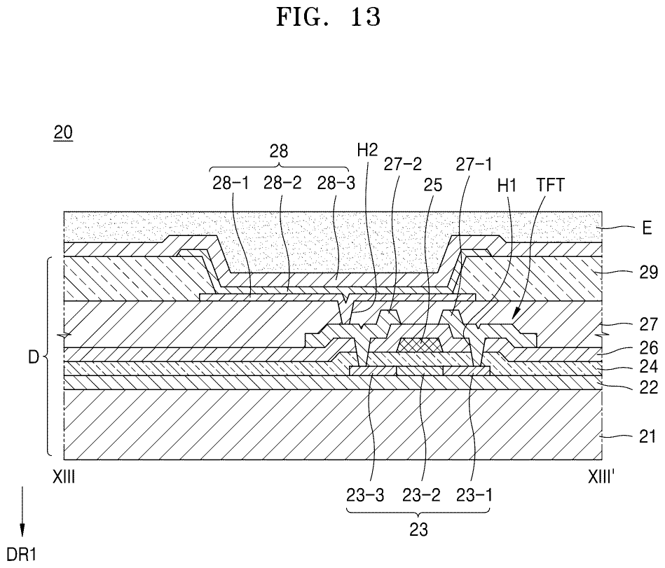

FIG. 12 is a plan view of a display device 20 manufactured using an apparatus for manufacturing a display device, according to an embodiment. FIG. 13 is a cross-sectional view of the display device 20 of FIG. 12, taken along a line XIII-XIII′ of FIG. 12.

Referring to FIGS. 12 and 13, the display device 20 may have a display area DA and a non-display area NDA defined on a substrate 21, the non-display area NDA arranged around the display area DA. A light-emitting element 28 may be arranged in the display area DA, and power wiring (not illustrated) may be arranged in the non-display area NDA. In some aspects, a pad portion C may be arranged in the non-display area NDA.

A plurality of deposition material patterns may be arranged in the display area DA. In some aspects, the display area DA may have an atypical shape.

The display device 20 may include the display substrate D, an intermediate layer 28-2 disposed on the display substrate D, and an opposite electrode 28-3 disposed on the intermediate layer 28-2. In some aspects, the display device 20 may include a thin-film encapsulation layer E disposed on the opposite electrode 28-3.

The display substrate D may include the substrate 21, a thin-film transistor TFT, a via layer 27, and a pixel electrode 28-1.

The substrate 21 may include a plastic material or a metal material. In some aspects, the substrate 21 may include polyimide (PI).

The thin-film transistor TFT may be disposed over the substrate 21, the via layer 27 may cover the thin-film transistor TFT, and the light-emitting element 28 may be disposed on the via layer 27.

A buffer layer 22 including an organic compound and/or an inorganic compound may be further disposed on an upper surface of the substrate 21, and the buffer layer 22 may contain SiOₓ (x≥1) and/or SiNₓ (x≥1).

After an active layer 23 arranged in a certain pattern is disposed on the buffer layer 22, the active layer 23 may be buried by a gate insulating layer 24. The active layer 23 may include a source region 23-1 and a drain region 23-3. The active layer 23 may further include a channel region 23-2 between the source region 23-1 and the drain region 23-3.

The active layer 23 may contain various materials. In an embodiment, the active layer 23 may contain an inorganic semiconductor material such as, for example, amorphous silicon or crystalline silicon. In another embodiment, the active layer 23 may contain an oxide semiconductor. In another embodiment, the active layer 23 may contain an organic semiconductor material. However, an example case where the active layer 23 is formed of amorphous silicon will be mainly described herein for convenience.

The active layer 23 may be formed by forming an amorphous silicon layer on the buffer layer 22, crystallizing the amorphous silicon layer into a polycrystalline silicon layer, and patterning the polycrystalline silicon layer. The active layer 23 may have the source region 23-1 and the drain region 23-3 doped with impurities based on the type of a thin-film transistor such as, for example, a driving thin-film transistor (not illustrated), a switching thin-film transistor (not illustrated), or the like.

A gate electrode 25 corresponding to the active layer 23 and an interlayer insulating layer 26 burying the gate electrode 25 may be disposed on an upper surface of the gate insulating layer 24. After a contact hole H1 is formed in the interlayer insulating layer 26 and the gate insulating layer 24, a source electrode 27-1 and a drain electrode 27-2 may be disposed on the interlayer insulating layer 26 to be in contact with the source region 23-1 and the drain region 23-3, respectively.

The via layer 27 is disposed on the thin-film transistor TFT, and the pixel electrode 28-1 of the light-emitting element 28 is disposed on the via layer 27. The pixel electrode 28-1 is in contact with the drain electrode 27-2 of the thin-film transistor TFT by a via hole H2 in the via layer 27. The via layer 27 may be formed of an inorganic material and/or an organic material of a single layer or two or more layers. The via layer 27 may be a planarization layer having a flat upper surface regardless of curves in a lower layer of the via layer 27 or may be curved along curves in a lower layer of the via layer 27.

After the pixel electrode 28-1 is disposed on the via layer 27, a pixel-defining layer 29 may be formed of an organic material and/or an inorganic material. The pixel-defining layer 29 may cover the pixel electrode 28-1 and the via layer 27 and may have an opening which exposes the pixel electrode 28-1.

The intermediate layer 28-2 and the opposite electrode 28-3 are disposed on the pixel electrode 28-1. In an embodiment, the opposite electrode 28-3 may be disposed over the entire surface of the display substrate D. In this example case, the opposite electrode 28-3 may be disposed on the intermediate layer 28-2 and the pixel-defining layer 29. Hereinafter, an example case where the opposite electrode 28-3 is disposed on the intermediate layer 28-2 and the pixel-defining layer 29 will be mainly described for convenience.

The pixel electrode 28-1 may serve as an anode and the opposite electrode 28-3 may serve as a cathode, and polarities of the pixel electrode 28-1 and the opposite electrode 28-3 may be reversed.

The pixel electrode 28-1 and the opposite electrode 28-3 are insulated from each other by the intermediate layer 28-2, and voltages of different polarities are applied to the intermediate layer 28-2 to cause light emission from the organic emission layer.

The intermediate layer 28-2 may include an organic emission layer. As another optional example, the intermediate layer 28-2 may include an organic emission layer, and the intermediate layer 28-2 may further include at least one of a hole injection layer, a hole transport layer, an electron transport layer, and an electron injection layer. The present embodiment is not limited thereto, and the intermediate layer 28-2 may include an organic emission layer and may further include various other functional layers (not illustrated).

In some aspects, the intermediate layer 28-2 may be formed through the apparatus described herein for manufacturing a display device. The intermediate layer 28-2 may include a plurality of intermediate layers 28-2, and the plurality of intermediate layers 28-2 may form the display area DA. In some aspects, the plurality of intermediate layers 28-2 may be apart from each other in the display area DA.

One unit pixel is made up of a plurality of sub-pixels, and the plurality of sub-pixels may emit light of various colors. For example, the plurality of sub-pixels may include sub-pixels that emit red light, green light, and blue light, respectively, and may include sub-pixels (not denoted) that emit red light, green light, blue light, and white light.

The sub-pixel described herein may include one intermediate layer 28-2. In some aspects, in an example in which one sub-pixel is formed, the intermediate layer 28-2 may be formed through the apparatus described herein for manufacturing a display device.

The thin-film encapsulation layer E may include a plurality of inorganic layers or may include an inorganic layer and an organic layer. The organic layer of the thin-film encapsulation layer E may be formed of a polymer, and more particularly, may be a single layer or a laminated layer formed of one of polyethylene terephthalate, polyimide, polycarbonate, epoxy, polyethylene, and polyacrylate. The inorganic layer of the thin film encapsulation layer E may be a single layer or a laminated layer including metal oxide or metal nitride. More particularly, the inorganic layer may include one of SiNₓ, Al₂O₃, SiO₂, and TiO₂. An externally exposed top layer of the thin-film encapsulation layer E may be an inorganic layer for preventing penetration of moisture into a light-emitting element.

The thin-film encapsulation layer E may include at least one sandwich structure with at least one organic layer between at least two inorganic layers. As another example, the thin-film encapsulation layer E may include at least one sandwich structure with at least one inorganic layer between at least two organic layers. As another example, the thin-film encapsulation layer E may include a sandwich structure with at least one organic layer between at least two inorganic layers and a sandwich structure with at least one inorganic layer between at least two organic layers.

According to one or more of the above embodiments, a mask sheet in which waves that may appear on the mask sheet due to tensile force when the mask sheet is fixed on a mask frame may be reduced may be implemented. In some aspects, embodiments of the present disclosure support implementing a method of manufacturing a mask assembly, whereby the waves described herein may be reduced. However, one or more embodiments described herein are not limited thereto.

Example aspects of methods and processes supported by aspects of the present disclosure are described herein. In the descriptions of the methods and processes herein, the operations may be performed in a different order than the order shown and/or described, or the operations may be performed in different orders or at different times. Certain operations may also be left out of the flowcharts, one or more operations may be repeated, or other operations may be added.

Embodiments of the present disclosure support one or more processes (methods) supportive of the features and embodiments described herein. Descriptions that an element “may be disposed,” “may be formed,” and the like include processes (methods) and techniques for disposing, forming, positioning, and modifying the element in accordance with example aspects described herein.

It should be understood that embodiments described herein should be considered in a descriptive sense and not for purposes of limitation. Descriptions of features or aspects within each embodiment should typically be considered as available for other similar features or aspects in other embodiments. While one or more embodiments have been described with reference to the figures, it will be understood by those of ordinary skill in the art that various changes in form and details may be made therein without departing from the spirit and scope as defined by the following claims.

What is claimed is:

1. A mask sheet fixed to a mask frame, the mask sheet comprising:
a first zone in which a plurality of holes are arranged;
a second zone outside the first zone and comprising an edge of the mask sheet;
a third zone between the first zone and the second zone and fixed to the mask frame; and
a plurality of grooves arranged in the second zone.

2. The mask sheet of claim 1, wherein, in a plan view, the mask sheet comprises a short side and a long side longer than the short side,
wherein the plurality of grooves extend in a direction in which the short side extends.

3. The mask sheet of claim 2, wherein the first zone comprises a first subzone overlapping the plurality of holes and a second subzone surrounding the first subzone,
wherein a length of at least one of the plurality of grooves in the direction in which the short side extends is greater than a length of the first subzone in the direction in which the short side direction extends.

4. The mask sheet of claim 1, wherein the plurality of grooves comprise:
a first groove arranged in a first surface of the mask sheet; and
a second groove arranged in a second surface of the mask sheet opposite to the first surface.

5. The mask sheet of claim 4, wherein at least one of a depth of the first groove and a depth of the second groove is equal to or less than half a thickness of the mask sheet.

6. The mask sheet of claim 4, wherein the first groove and the second groove are each provided in plurality,
wherein the plurality of first grooves are alternately arranged with the plurality of second grooves.

7. The mask sheet of claim 4, wherein the first groove is provided in plurality,
wherein a space between adjacent first grooves of the plurality of first grooves is equal to a width of each of the first grooves.

8. The mask sheet of claim 1, wherein the plurality of grooves are arranged in a grid form.

9. A method of manufacturing a mask assembly, the method comprising:
preparing a mask frame comprising an opening in a center and preparing a mask sheet, wherein the mask sheet comprises a first zone in which a plurality of holes are arranged;
aligning the mask frame and the mask sheet with each other such that the opening comprised in the mask frame and the first zone comprised in the mask sheet overlap each other;
tensioning the mask sheet in one direction by applying tensile force to the mask sheet;
fixing the mask sheet to the mask frame; and
removing a second zone of the mask sheet protruding beyond an edge of the mask frame,
wherein the mask sheet comprises a plurality of grooves arranged in the second zone.

10. The method of claim 9, wherein, in a plan view, the mask sheet comprises a short side and a long side longer than the short side,
wherein the plurality of grooves extend in a direction in which the short side extends.

11. The method of claim 10, wherein the first zone comprises a first subzone overlapping the plurality of holes in the mask sheet and a second subzone surrounding the first subzone,
wherein a length of at least one of the plurality of grooves in the direction in which the short side extends is greater than a length of the first subzone in the direction in which the short side extends.

12. The method of claim 9, wherein the plurality of grooves comprise:
a first groove arranged in a first surface of the mask sheet; and
a second groove arranged in a second surface of the mask sheet opposite to the first surface.

13. The method of claim 12, wherein at least one of a depth of the first groove and a depth of the second groove is equal to or less than half a thickness of the mask sheet.

14. The method of claim 12, wherein the first groove and the second groove are each provided in plurality,
wherein the plurality of first grooves are alternately arranged with the plurality of second grooves.

15. The method of claim 12, wherein the first groove is provided in plurality,
wherein a space between adjacent first grooves of the plurality of first grooves is equal to a width of each of the first grooves.

16. The method of claim 9, wherein the plurality of grooves are arranged in a grid form.

17. An apparatus for manufacturing a display device, the apparatus comprising:
a mask assembly; and
a deposition source facing the mask assembly and configured to spray a deposition material toward the mask assembly,
wherein the mask assembly is manufactured by a method comprising:
preparing a mask frame comprising an opening in a center and preparing a mask sheet, wherein the mask sheet comprises a first zone in which a plurality of holes are arranged;
aligning the mask frame and the mask sheet with each other such that the opening comprised in the mask frame and the first zone comprised in the mask sheet overlap each other;
tensioning the mask sheet in one direction by applying tensile force to the mask sheet;
fixing the mask sheet to the mask frame; and
removing a second zone of the mask sheet protruding beyond an edge of the mask frame,
wherein the mask sheet comprises a plurality of grooves arranged in the second zone.

18. The apparatus of claim 17, wherein, in a plan view, the mask sheet comprises a short side and a long side longer than the short side,
wherein the plurality of grooves extend in a direction in which the short side extends.

19. The apparatus of claim 17, wherein the plurality of grooves comprise:
a first groove arranged in a first surface of the mask sheet; and
a second groove arranged in a second surface of the mask sheet opposite to the first surface.

20. The apparatus of claim 17, wherein the plurality of grooves are arranged in a grid form.
